(19) United States
(12) Patent Application Publication
(10) Pub. No.: US 2019/0152131 A1
(43) Pub. Date: May 23, 2019

(54) STRETCHED FILM, METHOD FOR MANUFACTURING SAME, CIRCULAR POLARIZATION PLATE, AND DISPLAY DEVICE

(71) Applicant: ZEON CORPORATION, Chiyoda-ku, Tokyo (JP)

(72) Inventor: Takeshi ASADA, Tokyo (JP)

(73) Assignee: ZEON CORPORATION, Chiyoda-ku, Tokyo (JP)

(21) Appl. No.: 16/076,061

(22) PCT Filed: Feb. 28, 2017
(86) PCT No.: PCT/JP2017/007662

§ 371 Date: Aug. 7, 2018

(30) Foreign Application Priority Data
Feb. 29, 2016 (JP) 2016-037378

(51) Int. Cl. B29C 55/04; C08J 5/18; G02B 5/30; G02F 1/13363; H01L 51/50; H05B 33/02; H05B 33/10

(52) U.S. Cl. CPC B29C 55/04; C08J 5/18; G02B 5/3033; G02F 1/13363; G02F 2001/133638; H05B 33/02; H05B 33/10; G02B 5/3083; H01L 51/50

(57) ABSTRACT

A method for producing a stretched film including the steps of: stretching a long-length multilayer film (D) including a pre-stretch film (A) formed of a thermoplastic resin, a shrinkable film (B) having a shrinkage ratio in a lengthwise direction of the film under conditions of 140° C. and 60 seconds in the air of 10% or more and 40% or less, a shrinkage ratio in the widthwise direction thereof of 5% or less, and an adhesion layer (C) bonding the pre-stretch film (A) to the shrinkable film (B), at a stretching ratio of less than 1.5 times in a direction of 45°±15° with respect to the widthwise direction of the multilayer film (D), and peeling the shrinkable film (B) and the adhesion layer (C).

### FIELD

The present invention relates to a stretched film and a method for producing the same, and a circularly polarizing plate and a display device using the stretched film.

### BACKGROUND

An organic electroluminescent display device (this may be referred to hereinafter as “organic EL display device” as appropriate) includes an organic electroluminescent element (this may be referred to hereinafter as “organic EL element” as appropriate). The organic EL element usually includes an electrode and a light-emitting layer capable of emitting light by supplying an electrical charge from the electrode. An organic EL light-emitting device usually has a metal electrode disposed on a back side of the light-emitting layer with respect to an observer. Therefore, when the organic EL element is exposed to external light, external light may be reflected by the metal electrode. Such reflection of the external light may cause glare by the reflected light and undesirable appearance of external scenery, resulting in display quality impairment.

In order to suppress reflection of external light as described above, a technology of providing a circularly polarizing plate as an anti-reflective film in the organic EL display device has been hitherto proposed. As the circularly polarizing plate, a film having a polarizer and a phase difference film as a ¼ wave plate in combination is known. As the phase difference film, a stretched film obtained by stretching a thermoplastic resin film is known (Patent Literatures 1 and 2). Such a phase difference film is usually produced as a long-length stretched film by stretching a long-length pre-stretch film.

### CITATION LIST

### Patent Literature

Patent Literature 1: Japanese Patent Application Laid-Open No. 2007-233198 A

Patent Literature 2: Japanese Patent No, 2818983 B

### SUMMARY

### Technical Problem

In general, when a polarizer and a phase difference film are bonded to produce a circularly polarizing plate, the polarized light absorption axis of the polarizer and the slow axis of the phase difference film are adjusted so that the polarized light absorption axis and the slow axis intersect diagonally (for example, at a crossing angle of 45°), i.e., in a relationship that is not parallel to or perpendicular to each other. The polarizer is usually produced as a long-length film having a polarized light absorption axis in a lengthwise direction of the film. For example, in production of a circularly polarizing plate using a long-length phase difference film having a slow axis in a widthwise direction or lengthwise direction of the film, the phase difference film needs to be cut in a diagonal direction. However, when the long-length phase difference film is cut in a diagonal direction, many scrap ends are produced. This increases waste of the long-length phase difference film. In particular, in production of a circularly polarizing plate for a large display device, the amount of scrap ends is further increased and the waste amount is increased. Therefore, in order to improve productivity, it is desirable that a stretched film used as a phase difference film to produce a circularly polarizing plate has a slow axis in the diagonal direction.

The phase difference film used in production of the circularly polarizing plate is required to satisfy a relationship of “0<NZ factor<1.00”, and is preferably required to have an NZ factor of approximately 0.5. When the phase difference film having such an NZ factor is used, reflection of external light can be suppressed during viewing a display surface of a display device in an inclined direction. Herein, an inclined direction of a surface means a direction that is not parallel to or perpendicular to the surface, and specifically means a direction of polar angle of the surface having a range of more than 0° and less than 90°. It is thus desirable that the stretched film used as the phase difference film to produce a circularly polarizing plate has an NZ factor satisfying “0<NZ factor<1.00”.

When a stretched film having a slow axis in a diagonal direction and a desired NZ factor is produced as a phase difference film, it is usually necessary that the refractive index nz in a thickness direction that decreases at a predetermined ratio by a stretching treatment is adjusted to achieve the desired NZ factor. In order to adjust the refractive index nz in the thickness direction, it is required to control the molecule orientation in the thickness direction. However, it is difficult in prior art technology to perform stretching satisfying such requirements. Accordingly, it has to be difficult in the light of the principles to produce a phase difference film having desirable properties as described above.

For example, Patent Literature 1 proposes a technology for producing a phase difference film having an NZ factor of 0 to 1.0 by setting a diagonal stretching condition within a specific range. However, according to investigation of the present inventor, actually it is difficult to obtain an assumed effect in Patent Literature 1 by the technology described in Patent Literature 1. Specifically, in order to produce a phase difference film having desired properties by the technology described in Patent Literature 1, it is necessary to apply a forcible deformation force to the film through a certain force. However, the aforementioned forcible deformation force cannot be applied only by gripping both ends of the film by a tenter stretching machine and adjusting the deformation amount in the diagonal direction and the deformation angle. Therefore, in a phase difference film produced by the technology described in Patent Literature 1, the NZ factor in a widthwise direction of the film fluctuates and the yield in the widthwise direction of the film is decreased by deterioration of a surface such as a wrinkle.

Patent Literature 2 describes a technology in which a shrinkable film is used to add the aforementioned forcible deformation force and the stretching is performed with the shrinkable film bonded to an unstretched film. However, by the technology described in Patent Literature 2, it is not easy to control deformation in a thickness direction during stretching the unstretched film. In particular, in stretching that is easily made ununiform in a widthwise direction of the film in the light of its principles, such as the diagonal stretching, the shrinkage force of the shrinkable film is easily made ununiform in the widthwise direction of the film. Therefore, it is difficult to obtain a stretched film having uniform properties in the widthwise direction of the film. Specifically, it is difficult to make the in-plane orientation angle θ and the NZ factor of a prior-art stretched film uniform over a width as large as 1,300 mm or more.

The present invention has been made in view of the aforementioned problems. An object of the present invention is to provide a stretched film having a slow axis in a diagonal direction, an NZ factor within a specific range of 0<NZ factor<1.00, and a small fluctuation of an orientation angle θ and the NZ factor, in an area with a width of at least 1,300 mm; a method for producing a stretched film having a slow axis in a diagonal direction, an NZ factor within a specific range of 0<NZ factor<1.00, and a small fluctuation of an orientation angle θ and the NZ factor, in an area with a width of at least 1,300 mm; a circularly polarizing plate including the aforementioned stretched film; and a display device including a circularly polarizing film piece obtained by cutting out the circularly polarizing plate.

### Solution to Problem

The present inventor has extensively studied to achieve the object described above. As a result, the present inventor found that when a shrinkable film and a pre-stretch film are bonded to each other so that the maximum shrinking direction of the shrinkable film has a specific angle, and then stretched in a diagonal direction, a stretched film in which the optical properties in a widthwise direction of the film are uniform and the refractive index in a thickness direction is controlled to a desired value is easily obtained. Thus, the present invention has been completed.

That is, the present invention is as follows.

(1) A method for producing a stretched film comprising the steps of:

stretching a long-length multilayer film (D) including a pre-stretch film (A) formed of a thermoplastic resin, a shrinkable film (B) having a shrinkage ratio in a lengthwise direction of the film under conditions of 140° C. and 60 seconds in the air of 10% or more and 40% or less, a shrinkage ratio in the widthwise direction thereof of 5% or less, and an adhesion layer (C) bonding the pre-stretch film (A) to the shrinkable film (B), at a stretching ratio of less than 1.5 times in a direction of 45°±15° with respect to the widthwise direction of the multilayer film (D), and

peeling the shrinkable film (B) and the adhesion layer (C).

(2) The method for producing a stretched film according to (1), wherein the thermoplastic resin is a resin containing an alicyclic polyolefin.

(3) The method for producing a stretched film according to (1) or (2), wherein the shrinkable film (B) is a film obtained by stretching a primary film containing a polyester.

(4) The method for producing a stretched film according to any one of (1) to (3), wherein the stretching of the multilayer film (D) is performed by a tenter stretching method using a tenter stretching machine.

(5) The method for producing a stretched film according to (4), wherein a pulling tension applied to the multilayer film (D) at an outlet of the tenter stretching machine is more than 100 N/m, and less than 400 N/m.

(6) A long-length stretched film formed of a thermoplastic resin, wherein in an area thereof with a width of at least 1,300 mm,

an average value θa of an in-plane orientation angle θ with respect to a lengthwise direction of the stretched film satisfies 40°<θa<80°,

a difference θₘₐₓ−θₘᵢₙ between a maximum value θₘₐₓ and a minimum value θₘᵢₙ of the orientation angle θ is 2° or less, an average value NZa of an NZ factor satisfies 0<NZa<1.00, and

a difference NZₘₐₓ−NZₘᵢₙ between a maximum value NZₘₐₓ and a minimum value NZₘᵢₙ of the NZ factor is less than 0.10.

(7) The stretched film according to (6), wherein the average value NZa of the NZ factor is more than 0.20 and equal to or less than 0.8.

(8) A circularly polarizing plate comprising the stretched film according to (6) or (7).

(9) A display device comprising a circularly polarizing film piece obtained by cutting out the circularly polarizing plate according to (8).

### Advantageous Effects of Invention

According to the present invention, there can be provided a stretched film having a slow axis in a diagonal direction, an NZ factor within a specific range of 0<NZ factor<1.00, and a small fluctuation of an orientation angle θ and the NZ factor, in an area with a width of at least 1,300 mm; a method for producing a stretched film having a slow axis in a diagonal direction, an NZ factor within a specific range of 0<NZ factor<1.00, and a small fluctuation of an orientation angle θ and the NZ factor, in an area with a width of at least 1,300 mm; a circularly polarizing plate including the aforementioned stretched film; and a display device including a circularly polarizing film piece obtained by cutting out the circularly polarizing plate.

### BRIEF DESCRIPTION OF DRAWINGS

FIG. 1 is a plan view schematically illustrating an example of a tenter stretching machine used in stretching of a multilayer film (D).

### DESCRIPTION OF EMBODIMENTS

Hereinafter, the present invention will be described in detail with reference to embodiments and examples. However, the present invention is not limited to the following embodiments and examples, and may be freely modified for implementation without departing from the scope of claims of the present invention and the scope of their equivalents.

In the following description, a “long-length” film refers to a film having a length that is 5 times or more the width, and preferably a film having a length that is 10 times or more the width, and specifically refers to a film having a length that allow a film to be wound up in a roll shape for storage or transportation. The upper limit of the length of the long-length film is not particularly limited, although it may be set to a length that is, for example, 100,000 times or less the width.

In the following description, an in-plane orientation angle θ of a film refers to an angle of an in-plane slow axis of the film relative to a lengthwise direction of the film. In the following description, the “orientation angle θ” simply means an in-plane orientation angle θ, unless otherwise specified. In the following description, the “slow axis” simply means an in-plane slow axis, unless otherwise specified.

In the following description, an in-plane retardation Re of a film is a value represented by Re=(nx−ny)×d, unless otherwise specified. A thickness direction retardation Rth of a film is a value represented by Rth={(nx+ny)/2−nz}×d, unless otherwise specified. An NZ factor of a film is a value represented by (nx−nz)/(nx−ny), unless otherwise specified, and can be calculated by a formula 0.5+Rth/Re. In the formulae, nx represents a refractive index in a direction which gives, among directions perpendicular to the thickness direction of the film (in-plane directions), the maximum refractive index. ny represents a refractive index in a direction that is, among the aforementioned in-plane directions of the film, orthogonal to the direction giving nx. nz represents a refractive index in the thickness direction of the film, and d represents the thickness of the film. The measurement wavelength is 590 nm unless otherwise specified.

In the following description, a diagonal direction of a long-length film means a direction that is an in-plane direction of the film neither parallel nor perpendicular to the widthwise direction of the film, unless otherwise specified.

In the following description, a direction of an element being “parallel”, “perpendicular”, and “orthogonal” may allow an error within the range of not impairing the advantageous effects of the present invention, for example, within a range of ±5°, unless otherwise specified.

In the following description, “phase different plate”, “polarizing plate”, and “wave plate” include not only a rigid member, but also a flexible member such as a resin film, unless otherwise specified.

In the following description, in a member having a plurality of films, an angle formed by optical axes of the respective films (a polarized light absorption axis, a polarized light transmission axis, a slow axis, etc.) is an angle viewed from the thickness direction of the films, unless otherwise specified.

[1. Stretched Film]

The stretched film of the present invention is a long-length film formed of a thermoplastic resin. As the thermoplastic resin, a resin containing a thermoplastic polymer and an optional component as necessary may be used. Examples of the thermoplastic polymer may include a polycarbonate, triacetyl cellulose, a polyester, a polyether sulfone, a polyarylate, a polyimide, and an alicyclic polyolefin. Among these, in particular from the viewpoint of mechanical strength and heat resistance, a polycarbonate, a polyester, and an alicyclic polyolefin are preferable. An alicyclic polyolefin is more preferable, and an alicyclic polyolefin having an alicyclic structure in its main chain is particularly preferable.

Examples of the alicyclic structure contained in the alicyclic polyolefin may include a saturated alicyclic hydrocarbon (cycloalkane) structure, and an unsaturated alicyclic hydrocarbon (cycloalkene) structure. Among these, a cycloalkane structure is preferable from the viewpoint of mechanical strength and heat resistance.

The number of carbon atoms constituting the alicyclic structure is preferably 4 or more, and more preferably 5 or more, and is preferably 30 or less, more preferably 20 or less, and particularly preferably 15 or less, per one alicyclic structure. When the number of carbon atoms constituting the alicyclic structure falls within this range, mechanical strength, heat resistance, and moldability of the film are highly balanced.

The ratio of the structural unit having the alicyclic structure in the alicyclic polyolefin is preferably 55% by weight or more, further preferably 70% by weight or more, and particularly preferably 90% by weight or more. When the ratio of the structural unit having the alicyclic structure in the alicyclic polyolefin falls within this range, transparency and heat resistance are improved.

Examples of the alicyclic polyolefin may include a norbornene-based polymer, a monocyclic olefin-based polymer, a cyclic conjugated diene-based polymer, a vinyl alicyclic hydrocarbon-based polymer, and hydrogenated products of these. Of these, a norbornene-based polymer is suitable because of its favorable transparency and moldability.

Examples of the norbornene-based polymer may include a ring-opening polymer of a monomer having a norbornene structure and a hydrogenated product thereof; and an addition polymer of a monomer having a norbornene structure and a hydrogenated product thereof. Examples of the ring-opening polymer of the monomer having a norbornene structure may include a ring-opening homopolymer of one type of monomer having a norbornene structure, a ring-opening copolymer of two or more types of monomers having a norbornene structure, and a ring-opening copolymer of a monomer having a norbornene structure and another monomer copolymerizable therewith. Further, examples of the addition polymer of the monomer having a norbornene structure may include an addition homopolymer of one type of monomer having a norbornene structure, an addition copolymer of two or more types of monomer having a norbornene structure, and an addition copolymer of a monomer having a norbornene structure and another monomer copolymerizable therewith. Among these, a hydrogenated product of the ring-opening polymer of the monomer having a norbornene structure is particularly suitable from the viewpoint of transparency, moldability, heat resistance, low hygroscopicity, size stability, and lightweight property.

Examples of the monomer having a norbornene structure may include bicyclo[2.2.1]hept-2-ene (common name: norbornene), tricyclo[4.3.0.1^{2,5}]deca-3,7-diene (common name: dicyclopentadiene), 7,8-benzotricyclo[4.3.0.1^{2,5}]dec-3-ene (common name: methanotetrahydrofluorene), tetracyclo[4.4.0.1^{2,5}.1^{7,10}]dodeca-3-ene (common name: tetracyclododecene), and derivatives of these compounds (for example, those with a substituent on the ring). Examples of the substituent may include an alkyl group, an alkylene group, and a polar group. A plurality of these substituents, which may be the same as or different from each other, may be bonded to the ring. As the monomer having a norbornene structure, one type thereof may be solely used, and two or more types thereof may also be used in combination at any ratio.

Examples of the polar group may include a heteroatom, and an atomic group having a heteroatom. Examples of the heteroatom may include an oxygen atom, a nitrogen atom, a sulfur atom, a silicon atom, and a halogen atom. Specific examples of the polar group may include a carboxyl group, a carbonyloxycarbonyl group, an epoxy group, a hydroxyl group, an oxy group, an ester group, a silanol group, a silyl group, an amino group, a nitrile group, and a sulfone group. In order to obtain a stretched film having a small saturated water absorption ratio, it is preferable that the amount of the polar group is small, and it is further preferable that the monomer does not contain a polar group.

Examples of a monomer that is ring-opening copolymerizable with the monomer having a norbornene structure may include monocyclic olefins such as cyclohexene, cycloheptene, and cyclooctene, and derivatives thereof; and cyclic conjugated dienes such as cyclohexadiene and cycloheptadiene, and derivatives thereof. One type thereof may be solely used, and two or more types thereof may also be used in combination at any ratio.

The ring-opening polymer of the monomer having a norbornene structure may be produced, for example, by polymerizing or copolymerizing the monomer in the presence of a ring-opening polymerization catalyst.

Examples of a monomer that is addition copolymerizable with the monomer having a norbornene structure may include α-olefins of 2 to 20 carbon atoms such as ethylene, propylene, and 1-butene, and derivatives thereof; cycloolefins such as cyclobutene, cyclopentene, and cyclohexene, and derivatives thereof; and non-conjugated dienes such as 1,4-hexadiene, 4-methyl-1,4-hexadiene, and 5-methyl-1,4-hexadiene. Among these, α-olefins are preferable, and ethylene is more preferable. One type thereof may be solely used, and two or more types thereof may also be used in combination at any ratio.

The addition polymer of the monomer having a norbornene structure may be produced, for example, by polymerizing the monomer in the presence of an addition polymerization catalyst.

The aforementioned hydrogenated products of the ring-opening polymer and the addition polymer may be produced, for example, by hydrogenating an unsaturated carbon-carbon bond, preferably 90% or more thereof, in a solution of the ring-opening polymer or the addition polymer by bringing the polymer into contact with hydrogen in the presence of a hydrogenation catalyst containing a transition metal such as nickel, palladium, or the like.

Among the norbornene-based polymers, it is preferable that the polymer has an X: bicyclo[3.3.0]octane-2,4-diyl-ethylene structure and a Y: tricyclo[4.3.0.1^{2,5}]decane-7,9-diyl-ethylene structure as structural units, and that the amount of these structural units is 90% by weight or more relative to the entire structural units of the norbornene-based polymer, and the content ratio of X and Y is 100:0 to 40:60 by weight ratio of X:Y. By using such a polymer, the stretched film obtained can have excellent stability of optical properties without size change over a long period of time.

The weight-average molecular weight (Mw) of the polymer contained in the thermoplastic resin is preferably 15,000 or more, more preferably 18,000 or more, and particularly preferably 20,000 or more, and is preferably 50,000 or less, more preferably 45,000 or less, and particularly preferably 40,000 or less. When the weight-average molecular weight falls within this range, mechanical strength and moldability of the stretched film are highly balanced. Herein, the weight-average molecular weight is usually a polyisoprene-equivalent weight-average molecular weight measured by gel permeation chromatography using cyclohexane as a solvent. However, when the polymer is not dissolved in cyclohexane in the aforementioned gel permeation chromatography, the weight-average molecular weight is a polystyrene-equivalent weight-average molecular weight using toluene as a solvent.

The molecular weight distribution (weight-average molecular weight (Mw)/number-average molecular weight (Mn)) of the polymer contained in the thermoplastic resin is preferably 1.0 or more, more preferably 1.1 or more, and particularly preferably 1.2 or more, and is preferably 10.0 or less, more preferably 4.0 or less, and particularly preferably 3.5 or less.

The glass transition temperature Tg of the polymer contained in the thermoplastic resin is preferably 80° C. or higher, and more preferably 100° C. or higher, and is preferably 250° C. or lower. When the glass transition temperature falls within this range, deformation and stress generation of the stretched film under high temperatures can be suppressed, and thus durability of the stretched film can be improved.

The absolute value of the photoelastic coefficient of the polymer contained in the thermoplastic resin is preferably 10×10⁻¹²·Pa⁻¹ or less, more preferably 7×10⁻¹²·Pa⁻¹ or less, and particularly preferably 4×10⁻¹²·Pa⁻¹ or less. The photoelastic coefficient C is a value obtained by dividing the birefringence Δn by stress a, i.e., the photoelastic coefficient C is a value expressed by C=Δn/σ. When the absolute value of the photoelastic coefficient of the polymer contained in the thermoplastic resin is made small as described above, the fluctuation of the in-plane retardation of the stretched film can be reduced.

The ratio of the polymer in the thermoplastic resin is preferably 50% by weight to 100% by weight, more preferably 70% by weight to 100% by weight, and particularly preferably 90% by weight to 100% by weight.

The thermoplastic resin may contain, in addition to the above-described polymer, an optional component. Examples of the optional components may include a colorant such as a dye and a pigment; a plasticizer; a fluorescent brightener; a dispersant; a heat stabilizer; a light stabilizer; an ultraviolet absorber; an antistatic agent; an antioxidant; fine particles; and a surfactant. As the optional components, one type thereof may be solely used, and two or more types thereof may also be used in combination at any ratio.

The stretched film of the present invention satisfies the following requirements (I) to (IV) in an area with a width of at least 1,300 mm. In the following description, the area of the stretched film with a width of at least 1,300 mm satisfying the requirements (I) to (IV) is referred to as “specific area” as appropriate. That is, the stretched film of the present invention has the specific area with a width of at least 1,300 mm satisfying the following requirements (I) to (IV).

(I) The average value θa of an in-plane orientation angle θ with respect to a lengthwise direction of the stretched film in the specific area satisfies 40°<θa<80°.

(II) The difference θₘₐₓ−θₘᵢₙ between the maximum value θₘₐₓ and the minimum value θₘᵢₙ of the orientation angle θ of the stretched film in the specific area is 2° or less.

(III) The average value NZa of an NZ factor of the stretched film in the specific area satisfies 0<NZa<1.00.

(IV) The difference NZₘₐₓ−NZₘᵢₙ between the maximum value NZₘₐₓ and the minimum value NZₘᵢₙ of the NZ factor of the stretched film in the specific area is less than 0.10.

Hereinafter, the requirements (I) to (IV) will be described in detail.

The average value θa of the in-plane orientation angle θ of the stretched film with respect to the lengthwise direction in the specific area with a width of at least 1,300 mm is usually larger than 40°, preferably larger than 42°, and more preferably larger than 44°, and is usually less than 80°, preferably less than 78°, and more preferably less than 76° (requirement (I)). When the average value θa of the orientation angle θ falls within the aforementioned range, it becomes possible to produce a circularly polarizing plate by bonding the stretched film and a long-length polarizer with the lengthwise directions of these films being in parallel to each other. Consequently, the circularly polarizing plate can be produced by a roll-to-roll method, and therefore the productivity of the circularly polarizing plate can be improved. The specific average value θa of the orientation angle θ may be set according to a display device to which the circularly polarizing plate is applied.

The average value θa of the orientation angle θ of the stretched film may be measured by the following method.

In an area to be measured, the orientation angle θ of the stretched film is measured at an interval of 5 cm in a widthwise direction of the film. This measurement is performed five times at an interval of 1 m in the lengthwise direction of the film. The average of the obtained measured values is calculated, to determine the average value θa of the in-plane orientation angle θ of the stretched film in the area to be measured.

The difference θₘₐₓ−θₘᵢₙ between the maximum value θₘₐₓ and the minimum value θₘᵢₙ of the orientation angle θ of the stretched film in the specific area with a width of at least 1,300 mm is usually 2.0° or less, preferably 1.0° or less, and ideally 0° (requirement (II)). The difference θₘₐₓ−θₘᵢₙ between the maximum value θₘₐₓ and the minimum value θₘᵢₙ of the orientation angle θ represents a fluctuation of the orientation angle θ in the widthwise direction of the film. When a circularly polarizing plate produced using a stretched film having a small fluctuation of the orientation angle θ is used, the fluctuation of reflectance in a plane of a display device can be decreased. Accordingly, the display quality of the display device can be improved.

The difference θₘₐₓ−θₘᵢₙ between the maximum value θₘₐₓ and the minimum value θₘᵢₙ of the orientation angle θ of the stretched film may be measured by the following method.

In an area to be measured, the in-plane orientation angle θ of the stretched film is measured at an interval of 5 cm in the widthwise direction of the film. Among the measured values, the maximum value θₘₐₓ and the minimum value θₘᵢₙ of the orientation angle θ are specified. The difference θₘₐₓ−θₘᵢₙ between the maximum value θₘₐₓ and the minimum value θₘᵢₙ of the orientation angle θ of the stretched film in the area to be measured is determined by subtracting the minimum value θₘᵢₙ from the maximum value θₘₐₓ.

The average value NZa of the NZ factor of the stretched film in the specific area with a width of at least 1,300 mm is usually more than 0.00, preferably more than 0.20, and more preferably more than 0.30, and is usually less than 1.00, preferably 0.80 or less, and more preferably 0.70 or less (requirement (III)). When a circularly polarizing plate produced using a stretched film having an average value NZa of the NZ factor falling within such a range is used, an effect of suppressing reflection on a display surface of a display device in all directions can be obtained. Accordingly, the display quality of the display device can be improved. The specific average value NZa of the NZ factor may be set according to a display device to which the circularly polarizing plate is applied.

The average value NZa of the NZ factor of the stretched film may be measured by the following method.

In an area to be measured, the NZ factor of the stretched film is measured at an interval of 5 cm in the widthwise direction of the film. This measurement is performed five times at an interval of 1 m in the lengthwise direction of the film. The average of the obtained measured values is calculated, to determine the average value NZa of the NZ factor of the stretched film in the area to be measured.

The difference NZₘₐₓ−NZₘᵢₙ between the maximum value NZₘₐₓ and the minimum value NZₘᵢₙ of the NZ factor of the stretched film in the specific area with a width of at least 1,300 mm is usually less than 0.10, more preferably 0.08 or less, and ideally 0.00 (requirement (IV)). The difference NZₘₐₓ−NZₘᵢₙ between the maximum value NZₘₐₓ and the minimum value NZₘᵢₙ of the NZ factor represents a fluctuation of the NZ factor in the widthwise direction of the film. When a circularly polarizing plate produced using a stretched film having a small fluctuation of the NZ factor is used, occurrence of color unevenness in a display device can be suppressed. Accordingly, the display quality of the display device can be improved. This effect is particularly useful in a large display device with a wide display surface.

The difference NZₘₐₓ−NZₘᵢₙ between the maximum value NZₘₐₓ and the minimum value NZₘᵢₙ of the NZ factor of the stretched film may be measured by the following method.

In an area to be measured, the NZ factor of the stretched film is measured at an interval of 5 cm in the widthwise direction of the film. Among the measured values, the maximum value NZₘₐₓ and the minimum value NZₘᵢₙ of the NZ factor are specified. The difference NZₘₐₓ−NZₘᵢₙ between the maximum value NZₘₐₓ and the minimum value NZₘᵢₙ of the NZ factor of the stretched film in the area to be measured is determined by subtracting the minimum value NZₘᵢₙ from the maximum value

The average value Rea of the in-plane retardation Re of the stretched film in the specific area is preferably 100 nm to 300 nm. In particular, when the stretched film is used in production of an anti-reflective circularly polarizing plate of an organic EL display device, the average value Rea of the in-plane retardation Re is preferably 140 nm±40 nm and particularly preferably 140 nm±30 nm. According to a circularly polarizing plate produced using a stretched film having an average value Rea of in-plane retardation Re falling within such a range, favorable anti-reflective properties can be obtained.

The average value Rea of the in-plane retardation Re of the stretched film may be measured by the following method.

In an area to be measured, the in-plane retardation Re of the stretched film is measured at an interval of 5 cm in the widthwise direction of the film. This measurement is performed five times at an interval of 1 m in the lengthwise direction of the film. The average of the obtained measured values is calculated, to determine the average value Rea of the in-plane retardation Re of the stretched film in the area to be measured.

The difference Reₘₐₓ−Reₘᵢₙ between the maximum value Reₘₐₓ and the minimum value Reₘᵢₙ of the in-plane retardation Re of the stretched film in the specific area is preferably 5 nm or less, more preferably 4 nm or less, particularly preferably 3 nm or less, and ideally 0 nm. The difference Reₘₐₓ−Reₘᵢₙ between the maximum value Reₘₐₓ and the minimum value Reₘᵢₙ of the in-plane retardation Re represents a fluctuation of the in-plane retardation Re in the widthwise direction of the film. When a circularly polarizing plate produced using a stretched film having a small fluctuation of in-plane retardation Re is used, the display quality of a display device including the circularly polarizing plate can be improved.

The difference Reₘₐₓ−Reₘᵢₙ between the maximum value Reₘₐₓ and the minimum value Reₘᵢₙ of the in-plane retardation Re of the stretched film may be measured by the following method.

In an area to be measured, the in-plane retardation Re of the stretched film is measured at an interval of 5 cm in the widthwise direction of the film. Among the measured values, the maximum value Reₘₐₓ and the minimum value Reₘᵢₙ of in-plane retardation Re are specified. The difference Reₘₐₓ−Reₘᵢₙ between the maximum value Reₘₐₓ and the minimum value Reₘᵢₙ of the in-plane retardation Re of the stretched film in the area to be measured is determined by subtracting the minimum value Reₘᵢₙ from the maximum value Reₘₐₓ.

The content amount of a volatile component in the stretched film is preferably 0.1% by weight or less, more preferably 0.05% by weight or less, particularly preferably 0.02% by weight or less, and ideally 0.00% by weight. When the content amount of the volatile component is small as described above, changes in optical properties of the stretched film with the lapse of time, such as an in-plane retardation Re and a thickness direction retardation Rth, can be suppressed. Further, the size stability of the stretched film can be improved. Furthermore, the circularly polarizing plate and display device that are produced using the stretched film can be prevented from deteriorating, thereby maintaining display images favorable for an extended period of time.

The volatile component is a substance with a molecular weight of 200 or less that is contained in a film, and examples thereof may include a residual monomer and a solvent. The content amount of the volatile component may be quantified as the total amount of substances with a molecular weight of 200 or less contained in the film by dissolving the film in chloroform and then performing analysis using gas chromatography.

The saturated water absorption ratio of the stretched film is preferably 0.03% by weight or less, more preferably 0.02% by weight or less, particularly preferably 0.01% by weight or less, and ideally 0.00% by weight. When the saturated water absorption ratio falls within the aforementioned range, change with the lapse of time of an in-plane retardation and a thickness direction retardation Rth can be reduced. Furthermore, the circularly polarizing plate and display device that are produced using the stretched film can be prevented from deteriorating, thereby maintaining display images favorable for an extended period of time.

As described herein, a saturated water absorption ratio is a value expressed as a percentage of increase in weight of a film test piece as a result of immersion of the film test piece in water at 23° C. for 24 hours relative to the weight of the film test piece prior to immersion.

The stretched film preferably has a high transparency. Specifically, the total light transmittance of the stretched film is preferably 80% or more, more preferably 85% or more, and particularly preferably 90% or more. The haze of the stretched film is preferably 5% or less, more preferably 3% or less, particularly preferably 1% or less, and ideally 0%.

Total light transmittance may be measured using a spectrophotometer (an ultraviolet-visible-near infrared spectrophotometer “V-570” manufactured by JASCO Corporation) in accordance with JIS K0115. Haze may be measured using “turbidimeter NDH-300A” manufactured by Nippon Denshoku Industries Co., Ltd. in accordance with JIS K7361-1997.

The average thickness of the stretched film is preferably 20 μm or more, and more preferably 30 μm or more, and is preferably 80 μm or less, more preferably 60 μm or less, and particularly preferably 40 μm or less, from the viewpoint of mechanical strength.

The thickness unevenness of the stretched film in the widthwise direction is preferably 3 μm or less, more preferably 2 μm or less, and ideally 0 Here, the thickness unevenness of the stretched film refers to a difference between the maximum and minimum thicknesses of the stretched film. When the thickness unevenness of the stretched film falls within the aforementioned range, winding-up of the stretched film can be favorably performed.

The width of the stretched film is usually 1300 mm or more. The stretched film has the above-described specific area in at least part in the widthwise direction of the film. In particular, it is preferable that the entirety of the stretched film in the widthwise direction is the specific area satisfying all of the above-described requirements (I) to (IV).

[2. Method for Producing Stretched Film]

The stretched film described above may be produced by a method including steps of

stretching a long-length multilayer film (D) including a pre-stretch film (A) formed of a thermoplastic resin; a shrinkable film (B); and an adhesion layer (C) that is disposed between the pre-stretch film (A) and the thermoplastic film (B) and allows the pre-stretch film (A) and the shrinkable film (B) to bond to each other, and

peeling the shrinkable film (B) and the adhesion layer (C).

Usually this method is performed while the film is continuously conveyed in a lengthwise direction of the film. Accordingly, in this method, the lengthwise direction of the film is usually parallel to a film conveyance direction and an MD direction, and a widthwise direction of the film is parallel to a direction perpendicular to the film conveyance direction and a TD direction.

The aforementioned production method usually includes a step of bonding the long-length pre-stretch film (A) and the long-length shrinkable film (B) via the adhesion layer (C) to obtain the multilayer film (D).

[2.1. Step of Preparing Multilayer Film (D)]

In the step of preparing the multilayer film (D), the long-length pre-stretch film (A) and the long-length shrinkable film (B) are usually prepared and bonded to each other via the adhesion layer (C).

The pre-stretch film (A) is a long-length film formed of the same thermoplastic resin as one contained in the stretched film. By the stretching of the pre-stretch film (A), the stretched film can be obtained. The sizes including thickness and width of the pre-stretch film (A) may be appropriately set so that a desired stretched film is obtained.

For example, the pre-stretch film (A) may be produced by a molding method such as a cast molding method, an extrusion molding method, and an inflation molding method. Among these, an extrusion molding method is preferable because of small amount of remaining volatile component and excellent size stability. The pre-stretch film may be a film having a single-layer structure including only one layer. Alternatively, the pre-stretch film may be a film having a multilayer structure including two or more layers. For example, a pre-stretch film (A) having a multilayer structure may be produced by a method such as a coextrusion molding method, a film lamination method, and a coating method. Among these, a coextrusion molding method is preferable.

The shrinkable film (B) is a long-length film of which the shrinkage ratio in the lengthwise direction and widthwise direction of the film under conditions of 140° C. and 60 seconds in the air falls within a specific range. The “shrinkage ratio” is represented by “shrinkage ratio (%)=[{(size before shrinkage)−(size after shrinkage)}/(size before shrinkage)]×100”.

Specifically, the shrinkage ratio in the lengthwise direction of the shrinkable film (B) under conditions of 140° C. and 60 seconds in the air is usually 10% or more and preferably 15% or more, and usually 40% or less, preferably 35% or less, and more preferably 30% or less. When the shrinkage ratio in the lengthwise direction of the shrinkable film (B) is equal to or more than the lower limit value of the aforementioned range, the NZ factor of the stretched film less than 1.00 can be easily achieved, and fluctuation of the NZ factor in the widthwise direction of the stretched film can be decreased. When the shrinkage ratio in the lengthwise direction of the shrinkable film (B) is equal to or less than the upper limit value of the aforementioned range, occurrence of a wrinkle by stretching can be suppressed. Consequently, a surface state of the stretched film can be improved.

The shrinkage ratio in the widthwise direction of the shrinkable film (B) under conditions of 140° C. and 60 seconds in the air is usually 5% or less and preferably 3% or less, and the lower limit thereof is 0%. When the shrinkage ratio in the widthwise direction of the shrinkable film (B) is equal to or less than the upper limit value of the aforementioned range, fluctuation of optical properties in the widthwise direction of the stretched film can be suppressed.

The shrinkable film (B) may be formed of a thermoplastic resin. As the thermoplastic resin contained in the shrinkable film (B), a resin containing a thermoplastic polymer may be used. Examples of the thermoplastic polymer may include a polycarbonate, a polyester, a polyether sulfone, a polyarylate, a polyimide, and an alicyclic polyolefin. As these polymers, one type thereof may be solely used, and two or more types thereof may also be used in combination at any ratio. Among these, from the viewpoint of balance of heat resistance and shrinkage ratio, a polyester is preferable.

As the polyester, polyethylene terephthalate having main components of terephthalic acid as an acid component and ethylene glycol as a glycol component is suitable. As the acid component, in combination with terephthalic acid, an optional acid component such as isophthalic acid, and naphthalene dicarboxylic acid may be used. As the glycol component, in combination with ethylene glycol, an optional glycol component such as cyclohexane dimethanol, and neopentyl glycol may be used. They may be used at any ratio by copolymerization or polymer blending.

The thermoplastic resin contained in the shrinkable film (B) may also contain an optional component in combination with the above-described polymer in a range whereby the aforementioned shrinkage ratio can be achieved.

The shrinkable film (B) may be produced by stretching a primary film formed of a thermoplastic resin. The primary film may be produced by molding a thermoplastic resin by the same molding method as that described in the method for producing the pre-stretch film (A). Stretching may be performed by a stretching method such as a tenter stretching method, a roll stretching method, and the like. This stretching is usually performed as a uniaxial stretching in which the stretching is performed in only one direction. When the stretching ratio and stretching temperature are appropriately set during this stretching, the shrinkable film (B) having a desired shrinkage ratio can be produced.

As an adhesive for use in formation of the adhesion layer (C), an adhesive capable of bonding the pre-stretch film (A) to the shrinkable film (B) during stretching and being peeled from the pre-stretch film (A) after stretching may be used. Examples of such an adhesive may include an acrylic tackiness agent having weak tackiness. As the adhesive, one type thereof may be solely used, and two or more types thereof may also be used in combination at any ratio.

By bonding the pre-stretch film (A) and the shrinkable film (B) via the adhesive, the multilayer film (D) may be obtained. The shrinkable film (B) and the adhesion layer (C) are removed by peeling after stretching the multilayer film (D). For facilitating the peeling, it is preferable that the peel force between the shrinkable film (B) and the adhesion layer (C) is larger than the peel force between the pre-stretch film (A) and the adhesion layer (C). Herein, the peel force means a force required for peeling. Therefore, it is preferable that, before the bonding of the pre-stretch film (A) and the shrinkable film (B), a surface of the shrinkable film (B) is subjected to a surface treatment that can increase the peel force between the shrinkable film (B) and the adhesion layer (C). Examples of the surface treatment may include a corona treatment, a plasma treatment, and a flame treatment.

[2.2. Step of Stretching Multilayer Film (D)]

After the long-length multilayer film (D) is prepared, a step of stretching the multilayer film (D) is performed. In this step, stretching is usually performed by a tenter stretching method using a tenter stretching machine.

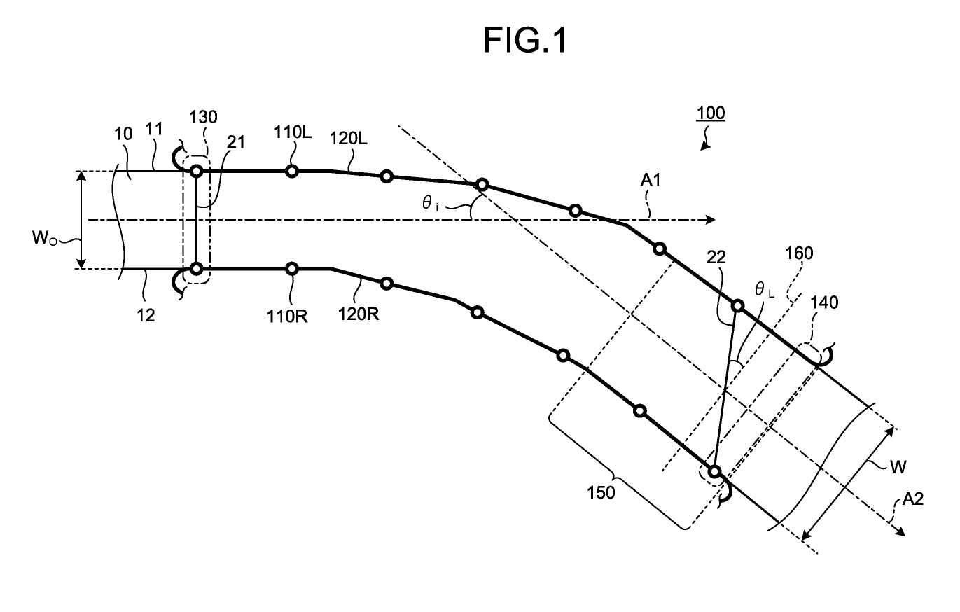

FIG. 1 is a plan view schematically illustrating an example of a tenter stretching machine 100 used in stretching of a multilayer film (D) 10.

As shown in FIG. 1, the tenter stretching machine 100 shown in this example is a machine for stretching the multilayer film (D) 10 fed from an unshown feeding roll in a diagonal direction of the film under a heating environment by an unshown oven.

The tenter stretching machine 100 includes a plurality of grippers 110L and 110R capable of gripping respective ends 11 and 12 in the widthwise direction of the multilayer film (D) 10 and a pair of rails 120L and 120R provided on respective sides of a film conveyance path for guiding the grippers 110L and 110R.

The grippers 110L and 110R are provided so as to move along the rails 120L and 120R. The grippers 110L and 110R are provided so as to move at a constant speed with keeping the constant intervals between the grippers 110L and 110R on the upstream side and the downstream side. The grippers 110L and 110R are provided so as to grip the both ends 11 and 12 in the widthwise direction of the multilayer film (D) 10 successively fed to the tenter stretching machine 100 at an inlet 130 of the tenter stretching machine 100 and release the both ends 11 and 12 at an outlet 140 of the tenter stretching machine 100.

The rails 120L and 120R have an asymmetric shape according to stretching conditions such as a stretching direction and a stretching ratio. In the tenter stretching machine 100 shown in this example, the shapes of the rails 120L and 120R are set such that the gap between the rails 120L and 120R is increased toward the downstream side and a travelling direction of the multilayer film (D) 10 is curved in a right direction. Herein, the travelling direction of the long-length multilayer film (D) 10 means a moving direction of a midpoint in the widthwise direction of the multilayer film (D) unless otherwise specified. In the description of the tenter stretching machine 100 shown in this example, “right” and “left” represent directions when a film to be conveyed in a horizontal state is observed from the upstream to the downstream of the conveyance direction unless otherwise specified.

Each of the rails 120L and 120R has an endless and continuous track such that the grippers 110L and 110R can circulate along a predetermined track. Therefore, the tenter stretching machine 100 has a configuration that allows the grippers 110L and 110R after releasing the multilayer film (D) 10 at the outlet 140 of the tenter stretching machine 100 to successively return to the inlet 130.

The stretching of the multilayer film (D) 10 by such a tenter stretching machine 100 is performed in the following manner.

The multilayer film (D) 10 is fed from the unshown feeding roll and continuously supplied to the tenter stretching machine 100.

In the tenter stretching machine 100, the both ends 11 and 12 of the multilayer film (D) 10 are successively held by the grippers 110L and 110R at the inlet 130. The multilayer film (D) 10 of which the both ends 11 and 12 are held is conveyed with the grippers 110L and 110R moving.

Herein, the rails 120L and 120R for guiding the grippers 110L and 110R of the tenter stretching machine 100 shown in this example are set in an asymmetrical manner as to the left and right sides. Of a pair of grippers 110L and 110R that face each other in a direction perpendicular to a travelling direction A1 of the multilayer film (D) 10 at the inlet 130 of the tenter stretching machine 100, one of them (in this example, a right gripper), the gripper 110R, moves earlier than the other (in this example, a left gripper), the gripper 110L. Consequently, stretching in the diagonal direction is performed. The multilayer film (D) 10 after stretching is released from the grippers 110L and 110R at the outlet 140 of the tenter stretching machine 100. If necessary, the both ends 11 and 12 in the direction of the film are trimmed and the multilayer film (D) 10 is wound in a roll shape to be collected.

In the tenter stretching machine 100 as described above, the travelling direction A1 of the multilayer film (D) 10 before stretching at the inlet 130 is usually parallel to a feeding direction of the multilayer film (D) 10 from the feeding roll. In the tenter stretching machine 100, a travelling direction A2 of the multilayer film (D) 10 after stretching at the outlet 140 is usually parallel to a direction of winding the multilayer film (D) in a roll shape after stretching. In stretching using the tenter stretching machine 100, a case where a straight line 21 connecting the pair of grippers 110L and 110R facing at the inlet 130 of the tenter stretching machine 100 is perpendicular to the travelling direction A1 of the multilayer film (D) 10 before stretching at the inlet 130 will be discussed. The pair of grippers 110L and 110R move so that the gripper 110R moves earlier than the gripper 110L, and reach a straight region 150 on an outlet side. Herein, the straight region 150 on the outlet side of the tenter stretching machine 100 is a region where the gap between the pair of grippers 110L and 110R is not changed anymore. When the pair of grippers 110L and 110R reach the straight region 150 on the outlet side after stretching, a straight line 22 connecting the pair of grippers 110L and 110R forms an angle θ_{L}, which is not 90°, with a direction 160 perpendicular to the travelling direction A2 of the multilayer film (D) 10 after stretching at the outlet 140 (that is, the widthwise direction of the multilayer film (D) 10). The angle θ_{L} is a stretching angle in stretching using the tenter stretching machine 100.

In order to obtain a desired stretched film, the multilayer film (D) 10 is stretched in a direction at the predetermined stretching angle θ_{L} relative to the widthwise direction 160 of the multilayer film (D) 10 in stretching using the tenter stretching machine 100. A specific range of the stretching angle θ_{L} is usually 45°±15° and preferably 45°±10°. When the multilayer film (D) 10 is stretched at the stretching angle θ_{L} falling within such a range, fluctuation of optical properties in the widthwise direction of the stretched film can be suppressed.

For example, when the pulling tension applied to the multilayer film (D) at the outlet 140 of the tenter stretching machine 100 is adjusted, the stretching angle θ_{L} can be changed without changing the orientation angle θ of the stretched film to be finally obtained. When molecular orientation in the lengthwise direction or widthwise direction of the film in an appropriate degree is preliminarily imparted to the pre-stretch film (A) before stretching the multilayer film (D) 10 by the tenter stretching machine 100, the stretching angle θ_{L} can be changed without changing the orientation angle θ of the stretched film to be finally obtained.

The stretching ratio R in stretching using the tenter stretching machine 100 is represented by the following Expression (1) using the width W₀ of the multilayer film (D) 10 before stretching, the width W of the multilayer film (D) after stretching, and the stretching angle θ_{L}.

$$R = \frac{W}{{W}_{0} cos {θ}_{L}} \qquad ( 1 )$$

For obtaining a desired stretched film, the stretching ratio R represented by Expression (1) falls within a specific range in stretching using the tenter stretching machine 100. The specific range of the stretching ratio R is usually less than 1.5 times and preferably 1.4 times or less. When the multilayer film (D) 10 is stretched at such a stretching ratio, thickness unevenness in the widthwise direction of the stretched film and fluctuation of the NZ factor can be decreased. The lower limit of stretching ratio R may be set according to the optical properties of the stretched film, and for example, may be larger than 1.0 time.

Since the stretching is performed in the diagonal direction, the travelling direction A1 of the multilayer film (D) 10 before stretching at the inlet 130 of the tenter stretching machine 100 is usually different from the travelling direction A2 of the multilayer film (D) 10 after stretching at the outlet 140. In this case, an angle between the travelling directions A1 and A2 of the multilayer film (D) 10 is referred to as a feeding angle θ₁. The feeding angle θ₁ is preferably larger than 30° and more preferably larger than 40°, and preferably less than 75° and more preferably less than 70°. When the feeding angle θ₁ is set within the aforementioned range in production of a stretched film having an average value θa of the orientation angle θ satisfying 40°<θa<80°, fluctuation of the optical properties in the widthwise direction of the stretched film can be effectively suppressed. Therefore, the width of a specific area having uniform optical properties can be increased.

The pulling tension T applied to the multilayer film (D) 10 at the outlet 140 of the tenter stretching machine 100 is preferably more than 100 N/m, and preferably less than 400 N/m and more preferably less than 350 N/m. When the pulling tension T falls within the aforementioned range, occurrence of a slack and a wrinkle of the stretched film, fluctuation of retardation Re in the widthwise direction of the film, and fluctuation of the orientation angle θ can be easily suppressed.

The stretching temperature in the stretching step is preferably Tg−5° C. or higher, more preferably Tg or higher, and particularly preferably Tg+3° C. or higher, and is preferably Tg+30° C. or lower, more preferably Tg+25° C. or lower, and particularly preferably Tg+20° C. or lower. Herein, Tg is the glass transition temperature of the thermoplastic resin contained in the pre-stretch film (A). When the stretching temperature is equal to or higher than the lower limit value of the aforementioned range, moldability can be improved and occurrence of defects such as craze can be suppressed. When the stretching temperature is equal to or lower than the upper limit value of the aforementioned range, the orientation of molecules contained in the pre-stretch film (A) is effectively promoted. Therefore, the optical properties such as retardation can be effectively expressed.

A temperature gradient may be imparted to the stretching temperature in the widthwise direction of the film in a stretching zone where stretching is performed by the tenter stretching machine 100. By imparting such a gradient, thickness unevenness in the widthwise direction of the stretched film to be produced can be further effectively suppressed.

By stretching as described above, the pre-stretch film (A) contained in the multilayer film (D) is stretched to become a stretched film. During stretching, the tensile force is applied to the pre-stretch film (A) by the grippers 110L and 110R. By the tensile force, the molecules contained in the pre-stretch film (A) are oriented to express the optical properties such as retardation.

During stretching, not only the tensile force by the grippers 110L and 110R but also the shrinkage force by the shrinkable film (B) are applied to the pre-stretch film (A). This shrinkage force usually acts as a force of orienting the molecules contained in the pre-stretch film (A) in the thickness direction. Consequently, an NZ factor of less than 1.00 can be expressed by stretching as described above.

Further, the tensile force given by the grippers 110L and 110R and the shrinkage force given by the shrinkable film (B) can be applied uniformly in the widthwise direction of the film under the stretching conditions as described above. Therefore, a multilayer film (D) containing a phase difference film having uniform optical properties in the widthwise direction of the film is obtained by stretching as described above.

[2.3. Step of Peeling Shrinkable Film (B) and Adhesion Layer (C)]

The multilayer film (D) obtained by stretching includes a stretched film obtained by stretching the pre-stretch film (A), the stretched shrinkable film (B), and the adhesion layer (C) bonding the stretched film to the shrinkable film (B). When the shrinkable film (B) and the adhesion layer (C) are peeled and removed from the multilayer film (D), the desired stretched film is obtained.

[2.4. Optional Step]

The aforementioned method for producing a stretched film may further include an optional step as long as the desired stretched film is obtained. For example, the method for producing a stretched film may include a step of performing a surface treatment on the produced stretched film and a step of winding the produced stretched film in a roll shape for collecting.

[3. Circularly Polarizing Plate]

The stretched film of the present invention may be used solely or in combination with another member. Examples of applications of the stretched film may include a phase difference plate and a viewing-angle compensation film. In particular, it is preferable that the stretched film is used in combination with a polarizer to obtain a circularly polarizing plate.

The circularly polarizing plate of the present invention includes the stretched film of the present invention and a polarizer. Since the stretched film of the present invention is a long-length film, the circularly polarizing plate is also a long-length film. As the polarizer, a member that transmits linearly polarized light during incidence of natural light may be used. Specific examples of the polarizer may include a film obtained by subjecting a film of a vinyl alcohol-based polymer, such as a polyvinyl alcohol and a partially formalized polyvinyl alcohol, to an appropriate treatment such as a dyeing treatment by iodine and a dichroic substance such as a dichroic dye, a stretching treatment, and a cross-linking treatment in an appropriate order by an appropriate procedure. In particular, a polarizer having excellent light transmittance and degree of polarization is preferable. The thickness of the polarizer is generally 5 μm to 80 μm but is not limited to this thickness.

The circularly polarizing plate may be produced by bonding the stretched film to the polarizer. The circularly polarizing plate may be produced by bonding films that have been cut out at a desired angle into an appropriate size. However, it is preferable that the circularly polarizing plate is produced by bonding a long-length stretched film to a long-length polarizer by a roll-to-roll method. The angle between the slow axis of the stretched film and the polarized light absorption axis of the polarizer upon bonding is preferably 45° or an angle close to 45°, and specifically 40° to 50°, as viewed in the thickness direction.

The stretched film may be provided on both faces or only one face of the polarizer. The number of stretched film provided in the circularly polarizing plate may be only one or two or more. Upon bonding, an adhesive may be used, if necessary.

In prior art, the polarizer includes a protective film on one face or both faces thereof. However, when the stretched film is provided, the stretched film acts as a protective film of the polarizer. Therefore, in the circularly polarizing plate including the stretched film of the present invention, a protective film provided in prior art can be omitted. This can contribute to a decrease in thickness of a display device.

The circularly polarizing plate may include an optional member in combination with the stretched film and the polarizer. Examples of the optional member may include a protective film that is provided between the stretched film and the polarizer and is capable of protecting the polarizer. As the protective film, an appropriate transparent film may be used. In particular, a film formed of a resin having excellent properties such as transparency, mechanical strength, thermal stability, and water shielding properties is preferable. Examples of the resin forming the protective film may include resins containing: an acetate polymer such as triacetyl cellulose; a polymer having an alicyclic structure; a polyester polymer such as a polyolefin polymer, a polycarbonate polymer, and polyethylene terephthalate; and a polymer such as a polyvinyl chloride polymer, a polystyrene polymer, a polyacrylonitrile polymer, a polysulfone polymer, a polyether sulfone polymer, a polyamide polymer, a polyimide polymer, and an acrylic polymer.

[4. Display Device]

The circularly polarizing plate may be applied to a display device. Such a display device includes a circularly polarizing film piece obtained by cutting out the long-length circularly polarizing plate. Since the optical properties such as the orientation angle θ and the NZ factor of the stretched film contained in the circularly polarizing film piece are uniform in the plane, this display device usually has favorable display quality. Examples of the display device may include a liquid crystal display device, an organic EL display device, a plasma display device, a field-emission display (FED) device, and a surface-conduction electron-emitter display (SED) device.

In a display device such as an organic EL display device, the circularly polarizing film piece may function as an anti-reflective film. When the circularly polarizing plate is provided on a surface of the display device so that a surface on the polarizer side faces toward a visual recognition side, it is possible to suppress reflection in the display device of light that is incident from the outside of the display device and emission of the light to the outside of the display device. As a result, glare on a display surface of the display device and undesirable appearance external scenery can be suppressed. Specifically, when light is incident from the outside of the display device, only a part of linearly polarized light passes through the polarizer, and then passes through the stretched film, resulting in circularly polarized light. The circularly polarized light is reflected on a component that reflects light in the display device (reflection electrode, etc.) and again passes through the stretched film, resulting in linearly polarized light having a polarization axis in a direction orthogonal to the polarization axis of the linearly polarized light that is incident. The light does not pass through the polarizer. Consequently, the anti-reflection function is achieved. At that time, the stretched film has an NZ factor satisfying 0<NZa<1.00. Therefore, even when the display surface of the display device is viewed in an inclined direction, reflection of external light can be suppressed.

When the circularly polarizing film piece is applied to a liquid crystal display device among display devices, a display mode of liquid crystal cell in the liquid crystal display device is not particularly restricted. Examples of the display mode of liquid crystal cell of the liquid crystal display device in which the circularly polarizing film piece may be applied may include an in-plane switching (IPS) mode, a vertical alignment (VA) mode, a multi-domain vertical alignment (MVA) mode, a continuous pinwheel alignment (CPA) mode, a hybrid alignment nematic (HAN) mode, a twisted nematic (TM) mode, a super twisted nematic (STN) mode, and an optical compensated bend (OCB) mode.

The display device may include a member other than the circularly polarizing film piece according to the type of the display device. For example, the display device may include an appropriate part such as a prism array sheet, a lens array sheet, a light diffusing plate, a backlight, and a brightness enhancing film as one layer or two or more layers at an appropriate position. Examples of the backlight may include a cold cathode tube, a mercury plane lamp, a light-emitting diode, and an electroluminescent element.

### EXAMPLES

Hereinafter, the present invention will be specifically described by illustrating Examples. However, the present invention is not limited to the Examples described below. The present invention may be optionally modified for implementation without departing from the scope of claims of the present invention and its equivalents. In the following description, “%” and “part” representing quantity are on the basis of weight, unless otherwise specified. The operation described below was performed under the conditions of normal temperature and normal pressure in the atmospheric air, unless otherwise specified.

[Evaluation Method]

[Method for Evaluating Orientation Angle]

The in-plane orientation angle θ of the stretched film was measured over the entire width of the stretched film at an interval of 5 cm in the widthwise direction of the stretched film using a high-speed retardation measurement device (“RE-200” manufactured by Otsuka Electronics Co., Ltd.). This measurement was performed five times at an interval of 1 m in the lengthwise direction of the film. The average of the obtained measured values was calculated, to determine the average value θa of the in-plane orientation angle θ of the stretched film. The minimum value θₘᵢₙ was subtracted from the maximum value θₘₐₓ among all the measured values in the widthwise direction of the film, to obtain the difference θₘₐₓ−θₘᵢₙ as a fluctuation of the orientation angle θ.

[Method for Evaluating Retardation]

The in-plane retardation Re of the stretched film was measured over the entire width of the stretched film at an interval of 5 cm in the widthwise direction of the stretched film using a high-speed retardation measurement device (“RE-200” manufactured by Otsuka Electronics Co., Ltd.). This measurement was performed five times at an interval of 1 m in the lengthwise direction of the film. The average of the obtained measured values was calculated, to determine the average value Rea of the in-plane retardation Re of the stretched film.

[Method for Evaluating NZ Factor]

The NZ factor of the stretched film was measured over the entire width of the stretched film at an interval of 5 cm in the widthwise direction of the stretched film using a polarimeter (“AXOSCAN” manufactured by Axometrics, Inc.). This measurement was performed five times at an interval of 1 m in the lengthwise direction of the film. The average of the obtained measured values was calculated, to determine the average value NZa of the NZ factor of the stretched film. The minimum value NZₘᵢₙ was subtracted from the maximum value NZₘₐₓ among all the measured values in the widthwise direction of the film, to obtain the difference NZₘₐₓ−NZₘᵢₙ as a fluctuation of the NZ factor.

[Method for Measuring Stretching Angle θ_{L}]

Among grippers for gripping ends on a right side of a multilayer film (D) and grippers for gripping ends on a left side thereof, a pair of grippers that faced each other were selected and marked at an inlet of a tenter stretching machine. A straight line connecting the selected grippers was perpendicular to the conveyance direction of the multilayer film (D) at the inlet of the tenter stretching machine. The selected grippers passed through the inside of the tenter stretching machine and reached a straight region on an outlet side of the tenter stretching machine. In the straight region on the outlet side, the angle between the straight line connecting the selected grippers and the widthwise direction of the multilayer film (D) was measured to determine a stretching angle θ_{L}.

[Method for Evaluating Surface State of Film]

The produced stretched film was observed and evaluated in accordance with the following criteria.

Good: production of the stretched film was successfully performed with the state of having no wrinkles over the entire width.

Poor: Wrinkles occur partially or entirely, and the external appearance was significantly deteriorated.

[Method for Evaluating Display Properties]

A commercially available organic EL display device (55-inch organic EL-TV panel manufactured by LG Chem Ltd.) was prepared. A circularly polarizing plate provided on an outermost surface of the organic EL display device was removed and the circularly polarizing film piece produced in each of Examples or Comparative Examples was bonded using a tackiness agent so that a polarizer of the circularly polarizing film piece faced toward a visual recognition side. After that, the organic EL display device was observed under external light and evaluated in accordance with the following criteria.

Good: Even when a display surface is observed in an inclined direction, the reflectance is reduced at a low level and the visibility is favorable.

Poor: When a display surface is observed in an inclined direction, the reflectance is high and the visibility is poor.

### Production Example 1. Production of Pre-Stretch Film (A)

Pellets of a norbornene-based resin (“ZEONOR1420R” available from ZEON CORPORATION, glass transition point: 137° C.) were dried at 100° C. for 5 hours. The pellets were supplied to an extruder, melted in the extruder, passed through a polymer pipe and a polymer filter, extruded from a T-die on a casting drum in a sheet shape, and cooled. Thus, a long-length pre-stretch film (A) having a thickness of 90 μm and a width of 900 mm was obtained. The produced pre-stretch film (A) was wound in a roll shape and collected.

### Production Example 2. Production of Shrinkable Film (B)

Pellets of a polyester (“PET-G 6763” available from Eastman Chemical Company) were dried at 120° C. for 5 hours. The pellets were supplied to an extruder, melted in the extruder, passed through a polymer pipe and a polymer filter at a resin temperature of 260° C., extruded from a T-die on a casting drum in a sheet shape, and cooled. Thus, a primary film having a thickness of 60 μm and a width of 1,500 mm was obtained.

The obtained primary film was continuously supplied to a roll-type longitudinal stretching device. The primary film was stretched in the lengthwise direction of the film by the longitudinal stretching device under conditions of a stretching temperature of 80° C. and a stretching ratio of 2 times. After that, both ends in the widthwise direction of the film were trimmed and the film was subjected to a corona treatment. Thus, a long-length shrinkable film (B) having a width of 900 mm and a thickness of 42 μm was obtained. The shrinkage ratio in the lengthwise direction of the shrinkable film (B) was 20% and the shrinkage ratio thereof in the widthwise direction was 2%, under conditions of 140° C. and 60 seconds in the air. The shrinkable film (B) was wound in a roll shape and collected.

### Production Example 3. Production of Multilayer Film (D)

The pre-stretch film (A) and the shrinkable film (B) were wound off from the rolls and bonded to each other by an ordinary method using an adhesive (acrylic tackiness agent “CS9621” available from Nitto Denko Corporation), to obtain a long-length multilayer film (D) including the pre-stretch film (A), the adhesion layer (C), and the shrinkable film (D) in this order. The multilayer film (D) was wound in a roll shape and collected.

### Example 1

(1-1. Production of Stretched Film)

A tenter machine provided with grippers capable of moving along rails was prepared. In the tenter machine, the feeding angle θᵢ was set to 45° and the stretching angle θ_{L} was set to 38°. The rail pattern of the tenter machine was adjusted so that a stretched film having an average value θa of the orientation angle θ of 45° was obtained.

The multilayer film (D) was wound off from the roll, conveyed in the lengthwise direction of the film, and supplied to the tenter stretching machine. By the tenter stretching machine, the multilayer film (D) was stretched at a stretching temperature of 135° C., a stretching ratio of 1.3 times, and a pulling tension at an outlet of the tenter stretching machine of 120 N/m. Both ends in the widthwise direction of the stretched multilayer film (D) were trimmed and the shrinkable film (B) and the adhesion layer (C) were peeled, to obtain a long-length stretched film with a width of 1,330 mm.

The orientation angle θ, in-plane retardation Re, NZ factor, and surface state of the obtained stretched film were evaluated by the aforementioned methods. The results are shown in Table 1. As seen from Table 1, the obtained stretched film was uniform in the widthwise direction of the film.

(1-2. Production of Circularly Polarizing Plate)

A long-length polarizing plate having a polarized light absorption axis in a lengthwise direction of the film (“HLC2-5618S” available from SANRITZ CORPORATION, thickness: 180 μm) and the aforementioned long-length stretched film were bonded to each other by a roll-to-roll method, to obtain a long-length circularly polarizing plate with a width of 1,330 mm. The circularly polarizing plate was cut out to have a circularly polarizing film piece of a size corresponding to a display surface of an organic EL display device for evaluation. The display properties were evaluated by the aforementioned method. As a result of evaluation, reflection on the entire display surface in all directions was suppressed and the display properties were favorable.

### Example 2

The shrinkable film (B) was changed to another one having the shrinkage ratio indicated in Table 1. A stretched film and a circularly polarizing plate were produced and evaluated in the same manner as in Example 1 except for the above matter.

### Examples 3 and 4

The stretching temperature and stretching ratio of the multilayer film (D) were changed as indicated in Table 1. Stretched films and circularly polarizing plates were produced and evaluated in the same manner as in Example 1 except for the above matters.

### Example 5

The shrinkable film (B) was changed to another one having the shrinkage ratio indicated in Table 1. The pulling tension at the outlet of the tenter stretching machine was changed as indicated in Table 1. A stretched film and a circularly polarizing plate were produced and evaluated in the same manner as in Example 1 except for the above matters.

### Examples 6 and 7

The shrinkable film (B) was changed to another one having the shrinkage ratio indicated in Table 1. The stretching angle θ_{L} of the multilayer film (D) and the pulling tension at the outlet of the tenter stretching machine were changed as indicated in Table 1. Stretched films and circularly polarizing plates were produced and evaluated in the same manner as in Example 1 except for the above matters.

### Comparative Examples 1 and 2

The shrinkable film (B) was changed to another one having the shrinkage ratio indicated in Table 1. Stretched films and circularly polarizing plates were produced and evaluated in the same manner as in Example 1 except for the above matter. As a result of evaluation, the NZ factor of the stretched films was more than 1.00 and the fluctuation thereof in the widthwise direction was at a large level. The performance of the display device using the circularly polarizing plates was poor.

### Comparative Example 3

The shrinkable film (B) was changed to another one having the shrinkage ratio indicated in Table 1. A stretched film and a circularly polarizing plate were produced and evaluated in the same manner as in Example 1 except for the above matter. As a result of the evaluation, occurrence of wrinkles during stretching was at a severe degree and the NZ factor and the orientation angle θ of the stretched film were largely fluctuated in the widthwise direction. The performance of the display device using the circularly polarizing plate was poor.

### Comparative Example 4

The shrinkable film (B) was changed to another one having the shrinkage ratio indicated in Table 1. The stretching temperature and stretching ratio of the multilayer film (D) were changed as indicated in Table 1. A stretched film and a circularly polarizing plate were produced and evaluated in the same manner as in Example 1 except for the above matters. As a result of evaluation, the NZ factor of the stretched film was more than 1.00, and the performance of the display device using the circularly polarizing plate was poor.

### Comparative Example 5

The shrinkable film (B) was changed to another one having the shrinkage ratio indicated in Table 1. The stretching angle θ_{L} of the multilayer film (D), the stretching temperature, and the pulling tension at the outlet of the tenter stretching machine were changed as indicated in Table 1. A stretched film and a circularly polarizing plate were produced and evaluated in the same manner as in Example 1 except for the above matters. As a result of evaluation, the NZ factor of the stretched film was more than 1.00, and the performance of the display device using the circularly polarizing plate was poor.

### Comparative Example 6

The shrinkable film (B) was changed to another one having the shrinkage ratio indicated in Table 1. The stretching angle θ_{L} of the multilayer film (D), the stretching temperature, and the pulling tension at the outlet of the tenter stretching machine were changed as indicated in Table 1. A stretched film and a circularly polarizing plate were produced and evaluated in the same manner as in Example 1 except for the above matters. As a result of the evaluation, the NZ factor of the stretched film was largely fluctuated in the widthwise direction. Due to the occurrence of wrinkles, the surface state of the stretched film was poor. The performance of the display device using the circularly polarizing plate was poor.

### Comparative Example 7

The shrinkable film (B) was changed to another one having the shrinkage ratio indicated in Table 1. A stretched film and a circularly polarizing plate were produced and evaluated in the same manner as in Example 1 except for the above matter. As a result of the evaluation, the NZ factor of the stretched film was largely fluctuated in the widthwise direction. Due to the occurrence of wrinkles, the surface state of the stretched film was poor. The performance of the display device using the circularly polarizing plate was poor.

[Results]

The results in Examples and Comparative Examples described above are collectively shown in the following Table 1. Abbreviations in Table 1 mean as follows.

Shrinkage ratio: the shrinkage ratio of a shrinkable film (B)

MD: the lengthwise direction of a film

TD: the widthwise direction of a film

Rea: the average value of the in-plane retardation of a stretched film

θa: the average value of the orientation angle of a stretched film

Δθ: the difference θₘₐₓ−θₘᵢₙ between the maximum value θₘₐₓ and the minimum value θₘᵢₙ of the orientation angle θ, which represents a fluctuation of the orientation angle θ in the widthwise direction of a film.

NZa: the average value of the NZ factor of a stretched film

ΔNZ: the difference NZₘₐₓ−NZₘᵢₙ between the maximum value NZₘₐₓ and the minimum value NZₘᵢₙ of the NZ factor, which represents a fluctuation of the NZ factor in the widthwise direction of a film.

TABLE 1
Results of Examples and Comparative Examples

| | | | Diagonal stretching conditions | | | | | | | | | | |
|---|---|---|---|---|---|---|---|---|---|---|---|---|---|
| | Shrinkage | | Stretching | Stretching | | Pulling | | | | | | | |
| | ratio (%) | | angle | temperature | Stretching | tension | Rea | θa | Δθ | | | Surface | Display |
| | MD | TD | θ L [°] | [° C.] | ratio | [N/m] | [nm] | [°] | [°] | NZa | ΔNZ | state | Properties |
| Ex. 1 | 20 | 2 | 38 | 135 | 1.3 | 120 | 140 | 45 | 1.3 | 0.60 | 0.07 | Good | Good |
| Ex. 2 | 30 | 3 | 38 | 135 | 1.3 | 120 | 140 | 45 | 1.0 | 0.50 | 0.06 | Good | Good |
| Ex. 3 | 20 | 2 | 38 | 138 | 1.4 | 120 | 140 | 45 | 1.3 | 0.70 | 0.07 | Good | Good |
| Ex. 4 | 20 | 2 | 38 | 141 | 1.2 | 120 | 140 | 45 | 1.3 | 0.50 | 0.05 | Good | Good |
| Ex. 5 | 20 | 1 | 38 | 135 | 1.3 | 150 | 140 | 45 | 0.8 | 0.60 | 0.05 | Good | Good |
| Ex. 6 | 20 | 1 | 45 | 135 | 1.3 | 110 | 140 | 46 | 1.3 | 0.70 | 0.07 | Good | Good |
| Ex. 7 | 20 | 1 | 50 | 135 | 1.3 | 100 | 140 | 55 | 0.8 | 0.60 | 0.06 | Good | Good |
| Comp. | 6 | 0 | 38 | 135 | 1.3 | 120 | 140 | 45 | 2.5 | 1.05 | 0.40 | Good | Poor |
| Ex. 1 | | | | | | | | | | | | | |
| Comp. | 3 | 0 | 38 | 135 | 1.3 | 120 | 140 | 45 | 2.5 | 1.10 | 0.30 | Good | Poor |
| Ex. 2 | | | | | | | | | | | | | |
| Comp. | 45 | 4 | 38 | 135 | 1.3 | 120 | 140 | 45 | 2.5 | 0.40 | 0.60 | Poor | Poor |
| Ex. 3 | | | | | | | | | | | | | |
| Comp. | 13 | 2 | 38 | 144 | 1.6 | 120 | 140 | 45 | 1.5 | 1.07 | 0.07 | Good | Poor |
| Ex. 4 | | | | | | | | | | | | | |
| Comp. | 13 | 2 | 27 | 133 | 1.3 | 200 | 140 | 43 | 1.5 | 1.03 | 0.07 | Good | Poor |
| Ex. 5 | | | | | | | | | | | | | |
| Comp. | 13 | 2 | 62 | 137 | 1.3 | 90 | 140 | 65 | 1.5 | 0.40 | 0.70 | Poor | Poor |
| Ex. 6 | | | | | | | | | | | | | |
| Comp. | 20 | 7 | 38 | 135 | 1.3 | 120 | 140 | 45 | 1.3 | 0.60 | 0.50 | Poor | Poor |
| Ex. 7 | | | | | | | | | | | | | |

### DISCUSSION

As seen from Table 1, in each of Examples 1 to 7, a stretched film having a slow axis in a diagonal direction, an NZ factor within a specific range of 0<NZ factor<1.00, and a small fluctuation of orientation angle θ and NZ factor, in an area with a width of at least 1,300 m was obtained. In all the stretched films in Examples 1 to 7, occurrence of wrinkles during stretching is suppressed. In display devices to which circularly polarizing plates produced using the stretched films were applied, reflection of external light as viewed in an inclined direction is suppressed. As confirmed from the results, a long-length stretched film suitable for production of a circularly polarizing plate can be stably produced by the production method of the present invention.

### REFERENCE SIGN LIST

10 multilayer film (D)
11 and 12 film widthwise direction end of multilayer film (D)
21 straight line connecting pair of grippers and facing at inlet of tenter stretching machine
22 straight line connecting pair of grippers when pair of grippers reach straight region on outlet side after stretching
100 tenter stretching machine
110L and 110R gripper
120L and 120R rail
130 inlet
140 outlet
150 straight region on outlet side
160 direction perpendicular to travelling direction of multilayer film (D) after stretching at outlet
θi feeding angle
θL stretching angle

1. A method for producing a stretched film comprising the steps of:
stretching a long-length multilayer film (D) including a pre-stretch film (A) formed of a thermoplastic resin, a shrinkable film (B) having a shrinkage ratio in a lengthwise direction of the film under conditions of 140° C. and 60 seconds in the air of 10% or more and 40% or less, a shrinkage ratio in the widthwise direction thereof of 5% or less, and an adhesion layer (C) bonding the pre-stretch film (A) to the shrinkable film (B), at a stretching ratio of less than 1.5 times in a direction of 45°±15° with respect to the widthwise direction of the multilayer film (D), and
peeling the shrinkable film (B) and the adhesion layer (C).

2. The method for producing a stretched film according to claim 1, wherein the thermoplastic resin is a resin containing an alicyclic polyolefin.

3. The method for producing a stretched film according to claim 1, wherein the shrinkable film (B) is a film obtained by stretching a primary film containing a polyester.

4. The method for producing a stretched film according to claim 1, wherein the stretching of the multilayer film (D) is performed by a tenter stretching method using a tenter stretching machine.

5. The method for producing a stretched film according to claim 4, wherein a pulling tension applied to the multilayer film (D) at an outlet of the tenter stretching machine is more than 100 N/m, and less than 400 N/m.

6. A long-length stretched film formed of a thermoplastic resin, wherein in an area thereof with a width of at least 1,300 mm,
an average value θa of an in-plane orientation angle θ with respect to a lengthwise direction of the stretched film satisfies 40°<0a<80°,
a difference θₘₐₓ−θₘᵢₙ between a maximum value θₘₐₓ and a minimum value θₘᵢₙ of the orientation angle θ is 2° or less,
an average value NZa of an NZ factor satisfies 0<NZa<1.00, and
a difference NZₘₐₓ−NZₘᵢₙ between a maximum value NZₘₐₓ and a minimum value NZₘᵢₙ of the NZ factor is less than 0.10.

7. The stretched film according to claim 6, wherein the average value NZa of the NZ factor is more than 0.20 and equal to or less than 0.8.

8. A circularly polarizing plate comprising the stretched film according to claim 6.

9. A display device comprising a circularly polarizing film piece obtained by cutting out the circularly polarizing plate according to claim 8.
